(19) United States
(12) Patent Application Publication
(10) Pub. No.: US 2026/0082505 A1
(43) Pub. Date: Mar. 19, 2026

(54) LOUDSPEAKER APPARATUS

(71) Applicant: Tymphany HK Limited, Wanchai (HK)

(72) Inventors: Cheng-En LIN, Taipei City (TW); Yu-Cheng CHANG, Taipei City (TW); Gee-Keong Hong, Taipei City (TW)

(21) Appl. No.: 19/033,782

(22) Filed: Jan. 22, 2025

(30) Foreign Application Priority Data
Sep. 18, 2024 (CN) 202411307453.9

(51) Int. Cl. H05K 7/20; H04R 1/02

(52) U.S. Cl. CPC H05K 7/20145; H04R 1/025; H05K 7/20154; H05K 7/20409

(57) ABSTRACT

A loudspeaker apparatus includes a case, a loudspeaker assembly, a heat sink, and an air deflector part. The loudspeaker assembly is disposed on the case. The heat sink is disposed on the case, and the heat sink is adjacent to the loudspeaker assembly. The air deflector part is disposed on the case, the air deflector part is arranged around the loudspeaker assembly and the heat sink, and airflow generated when the loudspeaker assembly vibrates to generate sound is deflected to the heat sink by the air deflector part.

### CROSS-REFERENCE TO RELATED APPLICATIONS

This application claims priority claims of China patent application No. CN202411307453.9 filed on Sep. 18, 2024 under 35 USC. § 119(e), the entire contents of which are hereby incorporated by reference.

### TECHNICAL FIELD

The present invention relates to a loudspeaker, in particular to a loudspeaker apparatus.

### BACKGROUND OF THE INVENTION

When a loudspeaker operates, some of the internal components, such as the power chip, the power supply, or the system-on-chip (collectively referred to as heat sources), generate heat. To dissipate heat from the heat sources of the loudspeaker, a heat sink is provided inside the loudspeaker. The heat sink can be disposed nearby a heat source. After heat generated by the heat source is transferred to the heat sink, the heat sink transfers heat to the case of the loudspeaker through the air inside the loudspeaker, and the case of the loudspeaker dissipates heat by transferring heat through contacting external air. Since the loudspeaker dissipates heat into the external air by heat conduction, it is difficult to dissipate heat efficiently. Therefore, current loudspeakers have the problem of low heat dissipation efficiency.

### SUMMARY OF THE INVENTION

An object of the present invention is to provide a loudspeaker apparatus for enhancing the heat dissipation efficiency of the loudspeaker, which includes a case, a loudspeaker assembly, a heat sink, and an air deflector part. The loudspeaker assembly is disposed on the case. The heat sink is disposed on the case, and the heat sink is adjacent to the loudspeaker assembly. The air deflector part is disposed on the case, the air deflector part is arranged around the loudspeaker assembly and the heat sink, and airflow generated when the loudspeaker assembly vibrates to generate sound is deflected to the heat sink by the air deflector part.

Optionally, the number of heat sinks is at least two, the loudspeaker assembly is located between the at least two heat sinks, the number of the air deflector parts is two, and the loudspeaker assembly and the heat sink are located between the two air deflector parts.

Optionally, the at least two heat sinks are evenly distributed around the loudspeaker assembly with respect to a central axis of the loudspeaker assembly.

Optionally, each of the air deflector parts includes two first straight segments and an arc segment, the two ends of the arc segment are respectively connected to one of the two first straight segments, the loudspeaker assembly is disposed between the arc segments of the two air deflector parts, and the at least two heat sinks are respectively disposed between the first straight segments of the two air deflector parts.

Optionally, each of the air deflector parts is in the shape of a long strip, the two air deflector parts are disposed parallel to each other, and the loudspeaker assembly and the at least two heat sinks are located between the two air deflector parts.

Optionally, wherein the heat sink includes an external heat dissipation part, the external heat dissipation part is exposed on the case, the external heat dissipation part includes a plurality of first ribs, a plurality of first gaps is defined between the adjacent first ribs, and external airflow flows in a direction away from the loudspeaker assembly through each of the first gaps.

Optionally, the heat sink further includes an internal heat dissipation part, the internal heat dissipation part is connected to the external heat dissipation part, the internal heat dissipation part is disposed within the case, the internal airflow generated when the loudspeaker assembly vibrates to generate sound flows over the internal heat dissipation part of the heat sink, the internal heat dissipation part includes a plurality of second ribs, a plurality of second gaps are defined between the adjacent second ribs, and internal airflow in the airflow flows in a direction away from the loudspeaker assembly through each of the second gaps.

Optionally, the loudspeaker apparatus further includes a first heat pipe and a second heat pipe, a third gap is defined between two of the second ribs, the first heat pipe abuts against the loudspeaker assembly, the second heat pipe abuts against a heat source, and the first heat pipe and the second heat pipe are embedded in the third gap.

Optionally, the loudspeaker apparatus further includes a first heat pipe abutting against the loudspeaker assembly, and the first heat pipe further abuts against the heat sink.

Optionally, the loudspeaker assembly further includes a concave accommodation space, and the first heat pipe is embedded in the concave accommodation space, wherein the shape and size of a cross-section of the concave accommodation space are identical to the shape and size of a cross-section of the first heat pipe.

Optionally, the loudspeaker apparatus further includes a thermal conductive member embedded in the loudspeaker assembly, and the thermal conductive member abuts against the first heat pipe.

Optionally, the first heat pipe includes a U-shaped middle section, and the U-shaped middle section abuts against a bottom of the loudspeaker assembly.

Optionally, the loudspeaker apparatus further includes a grille, wherein the heat sink includes an external heat dissipation part, the external heat dissipation part is exposed on the case, the grille covers the case, and the grille further covers the external heat dissipation part of the heat sink.

The present invention further provides a loudspeaker apparatus, which includes a case, a heat sink, and a loudspeaker assembly. The heat sink is disposed on the case, wherein the heat sink includes an external heat dissipation part, and the external heat dissipation part is exposed on the case. The loudspeaker assembly is disposed on the case, wherein external airflow generated when the loudspeaker assembly vibrates to generate sound flows over the external heat dissipation part of the heat sink.

The advantages of this disclosure lie are detailed in the following.

The combination of the case, the loudspeaker, the heat sink and the air deflector part are provided. The loudspeaker assembly is disposed on the case. The heat sink is disposed on the case, and the heat sink is adjacent to the loudspeaker assembly. The air deflector part is disposed on the case, the air deflector part is arranged around the loudspeaker assembly and the heat sink, and airflow generated when the loudspeaker assembly vibrates to generate sound is deflected to the heat sink by the air deflector part. Since the airflow generated when the loudspeaker assembly vibrates to generate sound flows over the heat sink and removes heat from the heat sink, the heat sink dissipates heat not only by thermal conduction but also by thermal convection. The loudspeaker apparatus is provided with two heat dissipation mechanisms, namely, thermal conduction and thermal convection, and the heat dissipation efficiency of the heat sink is thereby significantly enhanced.

The above description is only an overview of the technical solution of the present invention. To understand the technical means of the present invention more clearly and to be implemented in accordance with the contents of the description, the present invention is described in detail below with embodiments of the present invention and with accompanying drawings.

### BRIEF DESCRIPTION OF DRAWINGS

FIG. 1 is a three-dimensional view and a partial enlarged view of the loudspeaker apparatus in a first embodiment of the present invention, in which the right side of the case is truncated.

FIG. 2 is a three-dimensional view from another viewing angle of the loudspeaker apparatus in the first embodiment of the present invention, in which the front side of the case is truncated.

FIG. 3 is a schematic view of the loudspeaker apparatus vibrating to generate sound in the first embodiment of the present invention, in which the schematic view is a top view, the left side of the shell is truncated, and the top side of the shell is cut to show the cross-section.

FIG. 4 is an exploded view of the left heat sink and the first heat pipe of the loudspeaker apparatus in the first embodiment of the present invention, in which the front side of the case is truncated, and the heat sink is also shown in a partial enlarged view.

FIG. 5 is a cross-sectional view of the loudspeaker apparatus in the first embodiment of the present invention, in which the cross-section passes through the central axis of the loudspeaker assembly.

FIG. 6 is a three-dimensional view and a partial enlarged view of the loudspeaker apparatus in a second embodiment of the present invention, in which the right side of the case is truncated and the grille is omitted.

FIG. 7 is a three-dimensional view from another viewing angle of the loudspeaker apparatus in the second embodiment of the present invention, in which the front side of the case is truncated.

### DETAILED DESCRIPTION OF THE INVENTION

The implementation of the present invention is described below in relation to specific embodiments, and a person having ordinary skill in the art can easily understand the advantages and effects of the present invention from the contents disclosed in this detailed description.

It should be noted that, without conflict, the embodiments in the present invention and the features in the embodiments may be combined with each other. The present invention is described in detail below with reference to the drawings and in conjunction with embodiments. In order to enable a person having ordinary skill in the art to better understand the present invention, the technical scheme in the embodiments of the present invention will be clearly and completely described below in conjunction with the drawings in the embodiments of the present invention, and it is obvious that the described embodiments are only illustrations of a part of the present invention, not all embodiments. Based on the embodiments of the present invention, all other embodiments obtained by a person having ordinary skill in the art without creative work shall fall within the scope of protection of the present invention.

It should be noted that the terms “first”, “second”, etc. in the description and claims of the present invention and in the above-mentioned drawings are used to distinguish similar objects, and do not intend to describe a specific order or sequence. In addition, the terms “including” and “having” and any variation thereof are intended to encompass non-exclusive inclusions, e.g., a process, a method, a system, a product or an apparatus containing a series of steps or elements, but these terms do not intend to limit those steps or elements that are clearly listed, for they may include other steps or elements that are not clearly listed or are inherent to those processes, methods, products or equipment.

It should be noted that, unless otherwise expressly specified or qualified, the terms “mounted” and “connected” shall be construed broadly; for example, objects may be fixed, detachable, or integrally connected; they can be mechanically or electrically connected; they can be directly connected or indirectly through an intermediate medium; or they can be connected within two components. For a person having ordinary skill in the art, the specific meaning of the above terms in the present invention may be understood on a case-by-case basis.

### First Embodiment

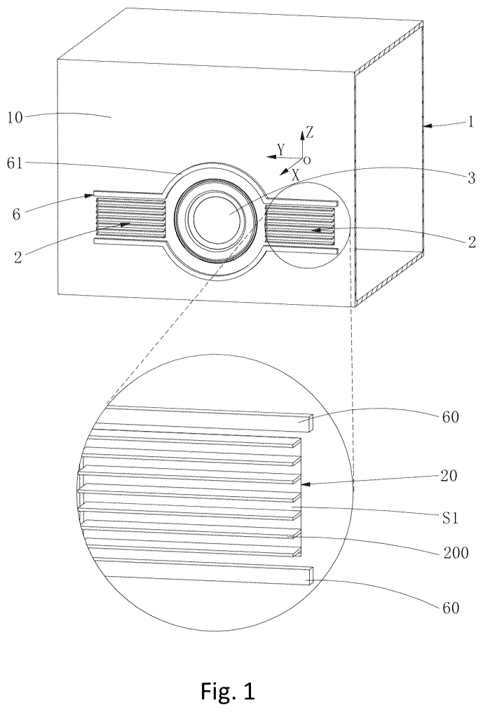

As shown in FIG. 1, the first embodiment provides a loudspeaker apparatus, which includes a case 1, a loudspeaker assembly 3, a heat sink 2, and an air deflector part 6. The loudspeaker assembly 3 is disposed on the case 1. The heat sink 2 is disposed on the case 1, and the heat sink 2 is adjacent to the loudspeaker assembly 3. The air deflector part 6 is disposed on the case 1, the air deflector part 6 is arranged around the loudspeaker assembly 3 and the heat sink 2, and airflow generated when the loudspeaker assembly 3 vibrates to generate sound is deflected to the heat sink 2 through the air deflector part 6.

As shown in FIG. 1, for illustrative purposes, the Cartesian coordinate system O-XYZ inside the loudspeaker apparatus is defined, where the X-axis of the Cartesian coordinate system O-XYZ and the loudspeaker assembly 3 are arranged coaxially and the XoY plane is parallel to the bottom wall or top wall of the case 1. The case 1 may be cuboid in shape, and the case 1 in the shape of a cuboid may include a lateral wall 10. The lateral wall 10 can be in the form of a rectangular sheet. The heat sink 2 and the loudspeaker assembly 3 can be disposed on the same side of the case 1. For example, the heat sink 2 and the loudspeaker assembly 3 can be fixed to the same lateral wall 10 of the case 1 by screwing, riveting or snapping. The central axis of the loudspeaker assembly 3 can be arranged perpendicular to the case 1. For example, the central axis of the loudspeaker assembly 3 can be arranged perpendicular to the lateral wall 10.

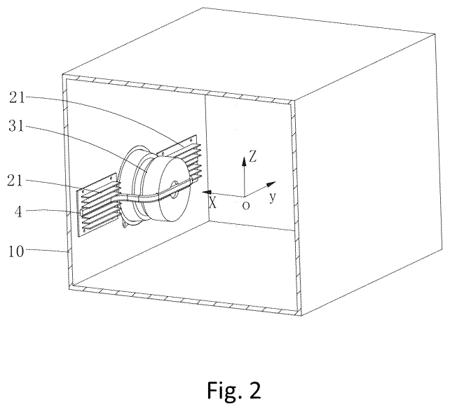

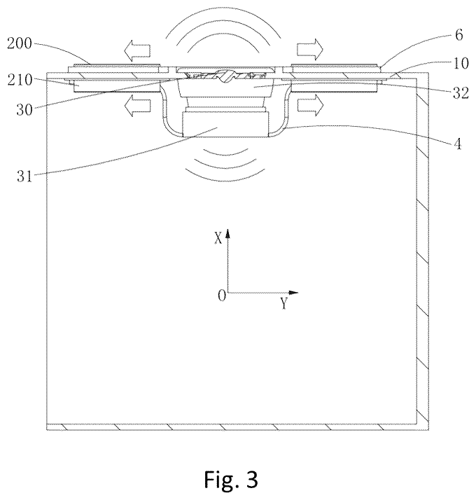

Referring to FIG. 2 and FIG. 3, the heat sink 2 (see FIG. 1 for the heat sink 2 hereinafter) includes an external heat dissipation part 20 (see FIG. 1 for the external heat dissipation part 20 hereinafter) and an internal heat dissipation part 21. When the heat sink 2 and the loudspeaker assembly 3 come into contact with the air inside and outside the case 1, the heat can be dissipated into the air by thermal conduction. The loudspeaker assembly 3 (see FIG. 1 for the loudspeaker assembly hereinafter) includes a diaphragm 30. The diaphragm 30 of the loudspeaker assembly 3 is configured to vibrate to generate sound in the direction of the X-axis to generate external airflow outside the case 1. The two arrows to the left and right in the upper part of the lateral wall 10 in FIG. 3 indicate the directions of the external airflow flowing over the external heat dissipation part 20, and the three short arcs in the upper part of the lateral wall 10 in FIG. 3 indicate the direction of the sound wave which the diaphragm 30 of the loudspeaker assembly 3 emits. The vibration of the diaphragm 30 of the loudspeaker assembly 3 to generate sound in the direction of the X-axis also generates internal airflow within the case 1. The two arrows to the left and right in the lower part of the lateral wall 10 in FIG. 3 indicate the directions of the internal airflow flowing over the internal heat dissipation part 21, and the three short arcs in the lower part of the lateral wall 10 in FIG. 3 indicate the direction of the sound wave emitted by the diaphragm 30 of the loudspeaker assembly 3. The external airflow flows in a radial direction of the loudspeaker 3 and away from the central axis of the loudspeaker assembly 3. For example, the external airflow can flow in the direction of the Y-axis so as to dissipate the heat from the heat sink 2 through the external heat dissipation part 20.

Referring to FIG. 2 and FIG. 3, the internal airflow flows in a radial direction of the loudspeaker assembly 3 (see FIG. 3 for the loudspeaker assembly 3 hereinafter) and away from the central axis of the loudspeaker assembly 3. For example, the internal airflow can flow in the direction of the Y-axis so as to dissipate the heat from the heat sink 2 (see FIG. 2 for the heat sink 2 hereinafter) through the internal heat dissipation part 21. Since the internal air temperature of the case 1 (see FIG. 1 for the case 1 hereinafter) is higher than the outside air temperature, the temperature difference between the temperature of the internal heat dissipation part 21 and the internal air temperature of the case 1 is less than the temperature difference between the temperature of the external heat dissipation part 20 (see FIG. 1 for the external heat dissipation part 20 hereinafter) and the temperature of the outside air. Thus, the heat dissipation efficiency of the internal heat sink part 21 is less than the heat dissipation efficiency of the external heat dissipation part 20. The case 1 can be made of a metal material with good thermal conductivity, such as aluminum alloy or steel. The heat sink 2 may be a block (such as a cuboid block) made of a metal material with good thermal conductivity (such as aluminum alloy or steel).

Referring to FIG. 2 and FIG. 3, the external portion of the heat sink 2, such as the external heat dissipation part 20 of the heat sink 2 (see FIG. 1 hereinafter), can be arranged higher than the outer surface of the lateral wall 10. The internal portion of the heat sink 2 (such as the internal heat dissipation part 21) can be arranged higher than the inner surface of the lateral wall 10. The external portion of the loudspeaker assembly 3 (such as the diaphragm of the loudspeaker assembly 3) can be arranged higher than the outer surface of the lateral wall 10. The internal portion of the loudspeaker assembly 3 (such as the magnet 31 or the frame 32) can be arranged higher than the inner surface of the lateral wall 10.

The combination of the case 1, the loudspeaker assembly 3, the heat sink 2 and the air deflector part 6 is provided. The loudspeaker assembly 3 is disposed on the case 1. The heat sink 2 is disposed on the case 1, and the heat sink 2 is adjacent to the loudspeaker assembly 3. The air deflector part 6 is disposed on the case 1, the air deflector part 6 is arranged around the loudspeaker assembly 3 and the heat sink 2, and airflow generated when the loudspeaker assembly 3 vibrates to generate sound is deflected to the heat sink 2 through the air deflector part 6. Since the airflow generated when the loudspeaker assembly 3 vibrates to generate sound flows over the heat sink 2 and removes heat from the heat sink 2, the heat sink 2 dissipates heat not only by thermal conduction but also by thermal convection. The loudspeaker apparatus is provided with two heat dissipation mechanisms, namely, thermal conduction and thermal convection, so the heat dissipation efficiency of the heat sink 2 is significantly enhanced.

As shown in FIG. 1, optionally, the number of the heat sinks 2 is at least two, and the loudspeaker assembly 3 is located between the at least two heat sinks 2. For example, the number of the heat sinks 2 can be two, and the loudspeaker assembly 3 can be located between the two heat sinks 2. The two heat sinks 2 can be respectively located on the left and right sides of the loudspeaker assembly 3. A greater number of the heat sinks 2 corresponds to a larger heat dissipation area of the loudspeaker unit 3.

As shown in FIG. 1, optionally, the at least two heat sinks 2 are evenly distributed around the loudspeaker assembly 3 with respect to a central axis of the loudspeaker assembly 3. The at least two heat sinks 2 evenly distributed around the loudspeaker assembly 3 with respect to a central axis of the loudspeaker assembly 3 can be arranged such that the heat sinks 2 surround the loudspeaker assembly 3, the distances from the centers of the heat sinks 2 to the central axis of the loudspeaker assembly 3 are equal, and the included angles between the connection lines from the centers of the heat sinks 2 to the central axis of the loudspeaker assembly 3 are equal.

Specifically, the central axis of the loudspeaker assembly 3 and the outer surface of the lateral wall 10 of the case 1 are vertically arranged, and the central axis and the outer surface intersect at an intersection point. Observing from the lateral wall 10 of the case 1, when the number of the heat sinks 2 is two, the two heat sinks 2 are located on a circumference of a circle where the aforementioned intersection point is the center of the circle, and the two heat sinks 2 are respectively located at the two ends of a diameter passing through the center of the circle. When the number of the heat sinks 2 is three, the angles between the central axes of the three heat sinks 2 connecting to the aforesaid intersection point are 120° respectively, and the distances between the centers of the three heat sinks 2 to the aforementioned intersection point are equal. When the number of the heat sinks 2 is four, the angles between the central axes of the four heat sinks 2 connecting to the aforementioned intersection point are 90° respectively, and the distances between the centers of the four heat sinks 2 to the aforementioned intersection point are equal, and so on. The at least two heat sinks 2 are evenly distributed around the loudspeaker assembly 3 with respect to a central axis of the loudspeaker assembly 3 such that the airflow generated by the vibration of the loudspeaker assembly 3 can be used in all directions, including external and internal airflow.

As shown in FIG. 1, optionally, when the number of the heat sinks 2 is two, the connection line connecting the centers of the two heat sinks 2 is perpendicular to the central axis of the loudspeaker assembly 3, and the connection line passes through the central axis of the loudspeaker assembly 3. When the heat sink body 22 of the heat sink 2 is a cuboid, the connection line of the centers of the heat sinks 2 is perpendicular to and passes through the central axis of the loudspeaker assembly 3 such that external airflow bounded by the center of each heat sinks 2 flows over heat dissipation parts including the external heat dissipation part 20 and the internal heat dissipation part 21 (see FIG. 2 for the internal heat dissipation part 21) so as to prevent partial overheating of each of the heat sinks 2. Specifically, observing from the lateral wall 10 of the case 1, when the two heat sinks 2 are disposed along the Y-axis, external airflow flows over the upper part and lower part of each of the heat sinks 2, in which the upper and lower parts of each the heat sinks 2 are bounded by a plane passing through the center of the heat sink 2 and parallel to the XoY plane.

As shown in FIG. 1, optionally, the external heat dissipation part 20 includes a plurality of first ribs 200, a plurality of first gaps S1 are defined between the adjacent first ribs 200, and the external airflow flows in a direction away from the loudspeaker assembly 3 through each of the first gaps S1. Each of the first ribs 200 and each of the first gaps S1 of each heat sink 2 can be in the shape of a long cuboid. Each of the first ribs 200 and each of the first gaps S1 of each heat sink 2 can be arranged parallel to each other. For example, the longitudinal directions of the first ribs 200 and the first gaps S1 of each heat sink 2 are parallel to the Y-axis.

As shown in FIG. 1, the external airflow can flow away from the loudspeaker assembly 3 in the direction of the Y-axis. The extension line of the longitudinal direction of the first rib 200 in the middle section of each external heat dissipation part 20 is perpendicular to and passes through the central axis of the loudspeaker assembly 3 such that each of the first ribs 200 and each of the first gaps S1 of the upper and lower parts of the external heat dissipation part 20 have external airflow flowing over them. That is, the external airflow is directed to flow over each of the first ribs 200 and each of the first gaps S1 located above the first ribs 200 in the middle section and each of the first ribs 200 and each of the first gaps S1 below the first ribs 200 located in the middle so as to prevent the external heat dissipation part 20 from being partially overheated due to a particular first rib 200 having no external airflow contacting it.

Each of the first ribs 200 and each the first gaps S1 can also be evenly distributed around the loudspeaker assembly 3 with respect to the central axis of the loudspeaker assembly 3, and the central axis of the loudspeaker assembly 3 can be arranged perpendicular to the longitudinal directions of the first ribs 200 and the first gaps S1.

As shown in FIG. 1, optionally, the loudspeaker apparatus 3 further includes an air deflector part 6, the air deflector part 6 is disposed on the case 1, the air deflector part 6 is arranged around the loudspeaker assembly 3 and the heat sink 2, and airflow generated when the loudspeaker assembly 3 vibrates to generate sound is deflected to the heat sink 2 through the air deflector part 6. The air deflector part 6 causes the airflow (including external airflow and/or internal airflow hereinafter) generated when the loudspeaker assembly 3 vibrates to generate sound to be concentrated in the direction toward the heat sink 2 such that the airflow that does not flow toward the heat sink 2 generated when the loudspeaker assembly 3 vibrates to generate sound can also be deflected in the direction of the heat sink 2 so as to increase the airflow through the heat sink 2 to enhance heat dissipation. The air deflector part 6 can be disposed on the lateral wall 10 of the case 1. For example, the air deflector part 6 may be disposed on the outer surface or the inner surface of the lateral wall 10 of the case 1. The air deflector part 6 can be connected to the lateral wall 10 of the case 1 by adhering, welding or integral molding.

As shown in FIG. 1, optionally, the number of the air deflector parts 6 can be two, and the heat sink 2 is located between the two air deflector parts 6. Each of the air deflector parts 6 includes two first straight segments 60 and an arc segment 61, and the two ends of the arc segment 61 are respectively connected to one of the two first straight segments 60. Two first straight segments 60 and the arc segment 61 can be integrally formed. The cross-section of the air deflector part 6 can be rectangular. The first straight segments 60 of the two air deflector parts 6 can be arranged parallel to each other. For example, each first straight segment 60 of each air deflector part 6 may be arranged parallel to the Y-axis. The two air deflector parts 6 may be arranged symmetrically in one plane with respect to the central axis of the loudspeaker assembly 3.

As shown in FIG. 1, the space between the two air deflector parts 6 is approximately equal to the width of the external heat dissipation part 20. The loudspeaker assembly 3 is disposed between the external heat dissipation parts 20 of the two heat sinks 2, and each of the heat sinks 6 is disposed between the two air deflector parts 6. Therefore, the airflow generated when the loudspeaker assembly 3 vibrates to generate sound is respectively deflected to the two external heat dissipation parts 20 so as to increase the airflow over the two external heat dissipation parts 20 to enhance heat dissipation.

As shown in FIG. 1, optionally, the number of the air deflector parts 6 is two, and the loudspeaker assembly 3 is located between the two air deflector parts 6. The connection line of the midpoint of the two air deflector parts 6 located in the upper and lower directions of the space may be perpendicular to and pass through the central axis of the loudspeaker assembly 3. The two air deflector parts 6 can be respectively located on the upper and lower sides of the loudspeaker assembly 3.

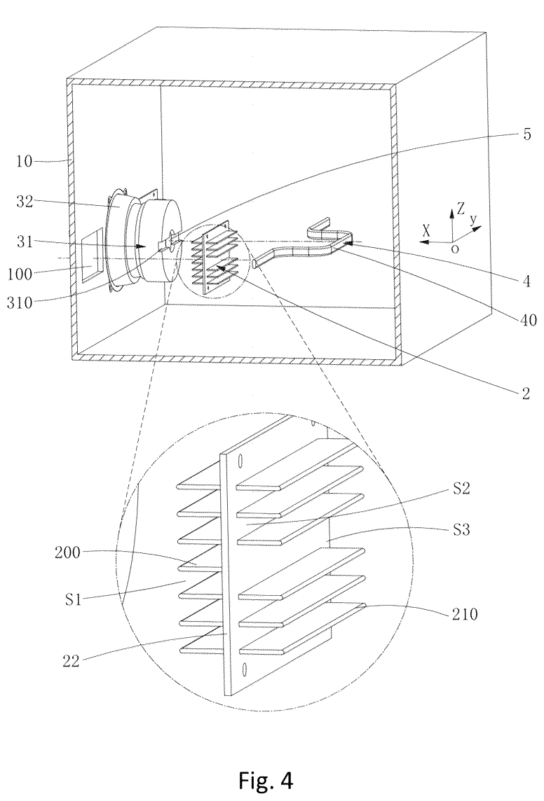

As shown in FIG. 4, optionally, the case 1 (see FIG. 1 for the case 1 hereinafter) is provided with a through hole 100, and the external heat dissipation part 20 (see FIG. 1 for the external heat dissipation part 20 hereinafter) of the heat sink 2 is disposed in the through hole 100. The number of the through holes 100 can be equal to the number of the heat sinks 2 and provided one on one. The external heat dissipation part 20 disposed in the through hole 100 is equivalent to the heat sink 2 being arranged through the case 1. The through hole 100 may be square and provided on the lateral wall 10 of the case 1. The external heat dissipation part 20 of the heat sink 2 is disposed in the through hole 100 to transfer heat from the inside of the case 1 to the outside of the case 1. Each of the first ribs 200 and each of the first gaps S1 of the external heat dissipation part 20 may be exposed via the through hole 100.

Referring to FIG. 1 and FIG. 2, optionally, the heat sink 2 further includes an internal heat dissipation part 21, the internal heat dissipation part 21 is connected to the external heat dissipation part 20, the internal heat dissipation part 21 is disposed within the case 1, and airflow generated when the loudspeaker assembly 3 vibrates to generate sound flows over the internal heat dissipation part 21 of the heat sink 2. The heat sink 2 includes a rectangular heat sink body 22 (see FIG. 4 for the heat sink body 22 hereinafter) that is flat in shape, the heat sink body 22 is disposed between the internal heat dissipation part 21 and the external heat dissipation part 20, and the heat sink body 22 is connected to the internal heat dissipation part 21 and external heat dissipation part 20. Each of the first ribs 200 (see FIG. 4 for the first ribs 200) can be vertically arranged on the outside of the heat sink body 22, and each of the second ribs 210 (see FIG. 4 for the second ribs 210) can be vertically arranged on the inside of the heat sink body 22. The airflow generated when the loudspeaker assembly 3 vibrates to generate sound may reach each internal heat dissipation part 21 through apertures of the frame 21 (FIG. 4 for the frame 21 hereinafter) of the loudspeaker assembly 3. The internal heat dissipation part 21, the external heat dissipation part 20, and the heat sink body 22 can be integrally formed. Alternatively, the heat sink body 22 may be fixed to the inner surface of the lateral wall 10 by screwing or riveting. The area of the heat sink body 22 is larger than the area of the through hole 100 of the case 1.

As shown in FIG. 4, optionally, the internal heat dissipation part 21 (see FIG. 4 for the internal heat dissipation part 21 hereinafter) includes a plurality of second ribs 210 and a plurality of second gaps S2 defined between the adjacent second ribs 210, and the internal airflow flows away from the loudspeaker assembly 3 (see FIG. 1 for the loudspeaker assembly 3) through each of the second gaps S2. Each of the second ribs 210 and each of the second gaps S2 of each heat sink 2 (see FIG. 1 for the heat sink 2 hereinafter) can be in the shape of a long strip of cuboids. The specifications (e.g., shape, size, and material) of the second rib 210 may be the same as those of the first rib 200. Each of the second ribs 210 and each of the second gaps S2 of each heat sink 2 are arranged parallel to each other. For example, the longitudinal directions of the second ribs 210 and the second gaps S2 of each heat sink 2 are parallel to the Y-axis.

As shown in FIG. 4, the internal airflow can flow away from the loudspeaker assembly 3 (see FIG. 3 for the loudspeaker assembly 3 hereinafter) along the Y-axis. The plane passing through the middle section of the internal heat dissipation part 21 (see FIG. 2 for the internal heat dissipation part 21 hereinafter) and parallel to the second ribs may be coplanar with the central axis of the speaker assembly 3 such that the internal airflow passes through each second rib 210 and each second gap S2 on the upper and lower sides of the internal heat dissipation part 21. That is, the internal airflow is directed to pass over each second rib 210 and each second gap S2 above the plane passing through the middle of the internal heat dissipation part 21 and parallel to the second ribs 210, and also, the internal airflow is directed to pass over each second rib 210 and each second gap S2 below the plane passing through the middle of the internal heat dissipation part 21 and parallel to the second ribs 210, so as to prevent the internal heat dissipation part 21 from being partially overheated due to a particular second rib 210 having no internal airflow contacting it.

Each of the second ribs 210 and each of the second gaps S2 of each heat sink 2 can also be evenly distributed with respect to the central axis of the loudspeaker assembly 3, and the central axis of the loudspeaker assembly 3 is perpendicular to the longitudinal direction of each of the second ribs 210 and each of the second gaps S2.

As shown in FIG. 4, optionally, the loudspeaker apparatus further includes a first heat pipe 4, the first heat pipe 4 abuts against the loudspeaker assembly 3 (see FIG. 1 for the loudspeaker assembly 3 hereinafter), and the first heat pipe 4 abuts against the heat sink 2 (see FIG. 1 for the heat sink 2 hereinafter). The first heat pipe 4 can be snapped or adhered to the loudspeaker assembly 3 or the heat sink 2. For example, the middle section of the first heat pipe 4 can be snapped or adhered to the bottom of the loudspeaker assembly 3. The left section of the first heat pipe 4 can be snapped or adhered to the internal heat dissipation part 21 (see FIG. 2 for the internal heat dissipation part 21 hereinafter) of the heat sink 2 positioned at the left side of the loudspeaker assembly 3. The right section of the first heat pipe 4 can be snapped or adhered to the internal heat dissipation part 21 of the heat sink 2 positioned at the right side of the loudspeaker assembly 3. The left and right sections of the first heat pipe 4 can be in the shape of long strips. The length of the left section of the first heat pipe 4 and the length of the right section of the first heat pipe 4 can be the same as the width of the internal heat dissipation part 21.

As shown in FIG. 4, optionally, the first heat pipe 4 includes a U-shaped middle section 40, and the U-shaped middle section 40 abuts against the bottom of the loudspeaker assembly 3 (see FIG. 1 for the loudspeaker assembly 3 hereinafter). The U-shaped middle section 40 can be snapped or adhered to the bottom of the loudspeaker assembly 3. The two ends of the U-shaped middle section are respectively connected to the left section of the first heat pipe 4 and the right section of the first heat pipe 4. The U-shaped middle section 40 of the first heat pipe 4 can be matched to the profile of the bottom of the loudspeaker assembly 3 so as to remove more heat from the loudspeaker assembly 3.

As shown in FIG. 4, optionally, a third gap S3 is defined between two second ribs 210, the first heat pipe 4 abuts against the loudspeaker assembly 3 (FIG. 1 for the loudspeaker assembly 3 hereinafter), and the first heat pipe 4 is embedded in the third gap S3. The width of the second gap S2 and the width of the first heat pipe 4 can be smaller than the width of the third gap S3. The third gap S3 can be arranged in parallel with the second gap S2 and is located at the middle position of the internal heat dissipation part 21 (see FIG. 2 for the internal heat dissipation part 21 hereinafter). The third gap S3 can be in the shape of a long cuboid. The left section of the first heat pipe 4 can be embedded or snapped in the third gap S3 at the middle section of the internal heat dissipation part 21 at the left side of the loudspeaker assembly 3. The right section of the first heat pipe 4 can be embedded or snapped in the third gap S3 at the middle section of the internal heat dissipation part 21 at the right side of the loudspeaker assembly 3. The first heat pipe 4 can be made of a material with good thermal conductivity, such as aluminum alloy or zinc alloy, or can be made by filling a closed metal tube with a liquid with good thermal conductivity (such as water or oil).

As shown in FIG. 4, optionally, the loudspeaker assembly 3 (see FIG. 1 for the loudspeaker assembly 3 hereinafter) includes a concave accommodation space 310, and the first heat pipe 4 is embedded in the concave accommodation space 310. The concave accommodation space 310 can be provided on the bottom of the loudspeaker assembly 3. The loudspeaker assembly 3 can further include a magnet 31, and the concave accommodation space 310 can be provided on the bottom of the magnet 31. For example, the concave accommodation space 310 can be provided such that it crosses the bottom of the magnet 31 of the loudspeaker assembly 3. The length of the concave accommodation space 310 can be approximately equal to the length of the bottom section of the U-shaped middle section 40 and the diameter of the magnet 31. The bottom section of the U-shaped middle section 40 may be embedded in the concave accommodation space 310. The concave accommodation space 310 is configured to fix the first heat pipe 4. Compared with the first heat pipe 4 directly abutting against the loudspeaker assembly 3, the concave accommodation space 310 increases the contact area between the loudspeaker assembly and the first heat pipe 4 to allow the first heat pipe 4 to remove more heat from the loudspeaker assembly 3.

As shown in FIG. 4, optionally, the shape and size of a cross-section of the concave accommodation space 310 are identical to the shape and size of a cross-section of the first heat pipe 4. For example, the cross-section of the concave accommodation space 310 and the cross-section of the first heat pipe 4 can be rectangular and have the same length and width. The shape and size of a cross-section of the concave accommodation space 310 being identical to the shape and size of a cross-section of the first heat pipe 4 allows the lateral sides of the first heat pipe to be fully in contact with the concave accommodation space 310 to rapidly remove heat from the loudspeaker assembly 3.

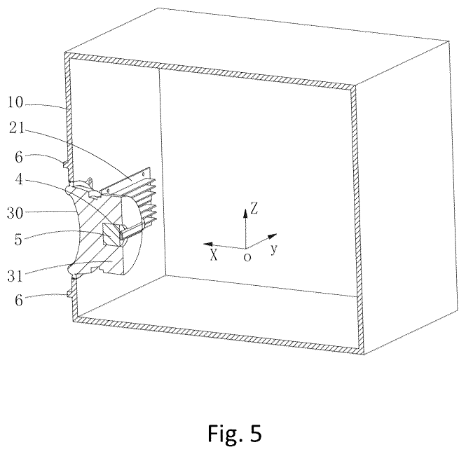

As shown in FIG. 5, optionally, the loudspeaker apparatus 3 further includes a thermal conductive member 5, the thermal conductive member 5 is embedded in the loudspeaker assembly 3 (see FIG. 1 for the loudspeaker assembly 3 hereinafter), and the thermal conductive member 5 abuts against the first heat pipe 4. The thermal conductive member 5 can be cylindrical. The central axis of the thermal conductive member 5 is arranged to be perpendicular to the middle point of the bottom section of the U-shaped middle section 40 (see FIG. 4 for the U-shaped middle section 40). The diameter of the thermal conductive member 5 can be larger than the width of the first heat pipe 4. The thermal conductive member 5 and the loudspeaker assembly 3 are arranged coaxially. The thermal conductive member 5 can be made of a material with good thermal conductivity, such as aluminum alloy or zinc alloy, or can be made by filling a closed metal tube with a liquid with good thermal conductivity (such as water or oil).

### Second Embodiment

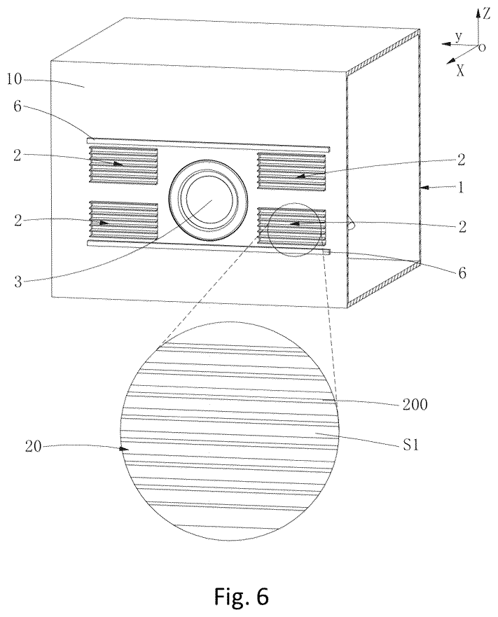

As shown in FIG. 6, the second embodiment provides a loudspeaker apparatus, and the loudspeaker apparatus of the second embodiment and the loudspeaker apparatus of the first embodiment are approximately the same. The differences between the second embodiment and the first embodiment are described below. In the second embodiment, when the number of the heat sinks 2 is four, the loudspeaker assembly 3 is located between the four heat sinks 2. The external heat dissipation part 20 of each heat sink 2 is embedded in a corresponding through hole 100 (see FIG. 4 for the through holes 100) provided on the case 1. The four heat sinks 2 can be arranged in two rows. For example, the four heat sinks 2 can be arranged in two rows parallel to the Z-axis.

As shown in FIG. 6, observing from the lateral wall 10 of the case 1, the four heat sinks 2 are arranged parallel to each other. The connection line between the middle point of the spacing of the two heat sinks 2 on the left side of the loudspeaker assembly 3 and the middle point of the spacing of the two heat sinks 2 on the right side of the loudspeaker assembly 3 may be perpendicular to and pass through the central axis of the loudspeaker assembly 3. The connection line between the middle point of the spacing of the two heat sinks 2 above the loudspeaker assembly 3 and the middle point of the spacing of the two heat sinks 2 below the loudspeaker assembly 3 may be perpendicular to and pass through the central axis of the loudspeaker assembly 3.

As shown in FIG. 6, optionally, the number of the air deflector parts 6 is two, and the air deflector parts 6 can be in the shape of long cuboids. The cross-section of the air deflector part 6 can be rectangular. The two air deflector parts 6 can be arranged parallel to each other. The four heat sinks 2 can be located between the two air deflector parts 6. The spacing between the two air deflector parts 6 and the sum of the widths of the two heat sinks 2 are approximately equal. The two air deflector parts 6 can be respectively located on the upper and lower sides of the four heat sinks 2. For example, each of the air deflector parts 6 may be arranged parallel to the Y-axis.

In the second embodiment, the loudspeaker apparatus may be equipped with a first heat pipe 4, a concave accommodation space 310 and a thermal conductive member 5, or the loudspeaker apparatus may be provided without a first heat pipe 4, a concave accommodation space 310 or a thermal conductive member 5. The second embodiment provided here is an embodiment that is not provided with the first heat pipe 4, the concave accommodation space 310 or the thermal conductive member 5.

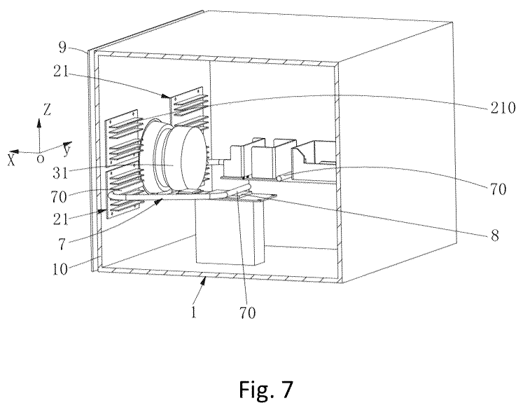

As shown in FIG. 7, optionally, the loudspeaker apparatus further includes a second heat pipe 7, a third gap S3 (see FIG. 4 for the third gap S3) is defined between two second ribs 210 (see FIG. 4 for the second rib 210), the second heat pipe 7 abuts against a heat source 8, and the second heat pipe 7 is embedded in the third gap S3. The third gap S3 can be arranged in parallel with the second gap S2 (see FIG. 4 for the second gap S2) and is located at the middle position of the internal heat dissipation part 21 (see FIG. 2 for the internal heat dissipation part 21 hereinafter). The cross-section of the second heat pipe 7 can be circular. The width of the third gap S3 is larger than the diameter of the second heat pipe 7. The number of the second heat pipes 7 and the number of the heat sources 8 are two respectively, and the second heat pipes 7 and the heat sources 8 are corresponding to each other.

As shown in FIG. 7, each of the second heat pipes 7 includes three second straight segments 70, and the three second straight segments 70 are connected to form a C-shape. One of the three second straight segments 70 abuts against the internal heat dissipation part 21 (see FIG. 2 for the internal heat dissipation part 21 hereinafter). For example, the second straight segment 70 can be embedded in the third gap S3 of the internal heat dissipation part 21. Another one of the three second straight segments 70 abuts against the heat source 8. For example, the second straight segment 70 abuts against an upper surface of the heat source 8. The second straight segment 70 abutting against the internal heat dissipation part 21 has a length greater than the length of the internal heat dissipation part 21. The second straight segment 70 abutting against the heat source 8 has a length greater than the width of the heat source 8.

As shown in FIG. 7, the heat source 8 can be an electronic component that generates heat when operating. For example, the heat source 8 may be a power chip, a power supply, or a system-on-chip. The heat source 8 can be disposed on a printed circuit board, and the printed circuit board can be fixed to the inner bottom of the case 1 (see FIG. 6 for the case 1) by a support. The second heat pipe 7 can be made of a material with good thermal conductivity, such as aluminum alloy or zinc alloy, or can be made by filling a closed metal tube with a liquid with good thermal conductivity (such as water or oil).

As shown in FIG. 7, the second heat pipe 7 can be embedded in the third gap S3 of the internal heat dissipation part 21 of the lower row of the four heat sinks 2 (see FIG. 1 for the heat sink 2, FIG. 2 for the internal heat dissipation part 21, and FIG. 4 for the third gap S3 hereinafter). For example, the second straight segment 70 of the second heat pipe 7 located at the left front of the loudspeaker assembly 3 (see FIG. 1 for the loudspeaker assembly 3 hereinafter) can be embedded in the third gap S3 of the internal heat dissipation part 21 of the heat sink 2 located at the lower left of the lateral wall 10 of the case 1. The second straight segment 70 of the second heat pipe 7 located at the left rear of the loudspeaker assembly 3 abuts against the left heat source 8. The second straight segment 70 of the second heat pipe 7 located at the right front of the loudspeaker assembly 3 can be embedded in the third gap S3 of the internal heat dissipation part 21 of the heat sink 2 located at the lower right of the lateral wall 10 of the case 1. The second straight segment 70 of the second heat pipe 7 located at the right rear of the loudspeaker assembly 3 abuts against the right heat source 8.

Referring to FIG. 6 and FIG. 7, optionally, the loudspeaker apparatus further includes a grille 9, the heat sink 2 includes an external heat dissipation part 20, the external heat dissipation part 20 is exposed on the case 1, the grille 9 covers the case 1, the grille 9 covers the external heat dissipation part 20 of the heat sink 2, and the area of the grille 9 can be approximately the same as the area of the lateral wall 10 of the case 1. The grille 9 covering the external heat dissipation part 20 of the heat sink 2 can prevent the user from suffering a burn injury caused by touching the external heat dissipation part 20. The grille 9 can be made of heat-insulating material, such as asbestos, foamed plastic, wood, etc. The grille 9 can be fixed to the air deflector part 6 or case 1. For example, the grille 9 can be fixed to the air deflector part 6 by adhering. The grille 9 can be fixed to the case 1 by adhering, screwing, or riveting.

What is claimed is:

1. A loudspeaker apparatus, comprising:
a case;
a loudspeaker assembly disposed on the case;
a heat sink disposed on the case and adjacent to the loudspeaker assembly; and
an air deflector part disposed on the case and arranged around the loudspeaker assembly and the heat sink,
wherein airflow generated when the loudspeaker assembly vibrates to generate sound is deflected to the heat sink by the air deflector part.

2. The loudspeaker apparatus as claimed in claim 1, wherein the heat sink is one of at least two,
wherein the loudspeaker assembly is located between the at least two heat sinks,
wherein the air deflector part is one of two air deflector parts, and
wherein the loudspeaker assembly and the at least two heat sinks are located between the two air deflector parts.

3. The loudspeaker apparatus as claimed in claim 2, wherein the at least two heat sinks are evenly distributed around the loudspeaker assembly with respect to a central axis of the loudspeaker assembly.

4. The loudspeaker apparatus as claimed in claim 2, wherein each of the air deflector parts includes:
two first straight segments; and
an arc segment having two ends respectively connected to the two first straight segments,
wherein the loudspeaker assembly is disposed between the arc segments of the two air deflector parts, and
wherein the at least two heat sinks are disposed between the first straight segments of the two air deflector parts.

5. The loudspeaker apparatus as claimed in claim 2, wherein each of the air deflector parts is in the shape of a long strip and is disposed parallel to each other, and
wherein the loudspeaker assembly and the at least two heat sinks are located between the two air deflector parts.

6. The loudspeaker apparatus as claimed in claim 1, wherein the heat sink includes an external heat dissipation part exposed on the case, the external heat dissipation part including a plurality of first ribs,
wherein a plurality of first gaps are defined between the adjacent first ribs, and
wherein an external airflow of the airflow flows in a direction away from the loudspeaker assembly through each of the first gaps.

7. The loudspeaker apparatus as claimed in claim 6, wherein the heat sink further includes an internal heat dissipation part,
wherein the external heat dissipation part is connected to the external heat dissipation part,
wherein the internal heat dissipation part is disposed within the case,
wherein an internal airflow of the airflow generated when the loudspeaker assembly vibrates to generate sound flows over the internal heat dissipation part of the heat sink,
wherein the internal heat dissipation part includes a plurality of second ribs,
wherein a plurality of second gaps are defined between the adjacent second ribs, and
wherein the internal airflow flows in a direction away from the loudspeaker assembly through each of the second gaps.

8. The loudspeaker apparatus as claimed in claim 7, further comprising:
a first heat pipe abutting against the loudspeaker assembly; and
a second heat pipe abutting against a heat source,
wherein a third gap is defined between two of the second ribs, and
wherein the first heat pipe and the second heat pipe are embedded in the third gap.

9. The loudspeaker apparatus as claimed in claim 1, further comprising a first heat pipe abutting against the loudspeaker assembly and the heat sink.

10. The loudspeaker apparatus as claimed in claim 9, wherein the loudspeaker assembly further includes a concave accommodation space,
wherein he first heat pipe is embedded in the concave accommodation space, and
wherein a shape and a size of a cross-section of the concave accommodation space are identical to a shape and a size of a cross-section of the first heat pipe.

11. The loudspeaker apparatus as claimed in claim 9, further comprising a thermal conductive member embedded in the loudspeaker assembly and abutting against the first heat pipe.

12. The loudspeaker apparatus as claimed in claim 9, wherein the first heat pipe includes a U-shaped middle section, and the U-shaped middle section abuts against a bottom of the loudspeaker assembly.

13. The loudspeaker apparatus as claimed in claim 1, further comprising a grille covering the case, wherein the heat sink includes an external heat dissipation part exposed on the case, and
wherein the grille covers the external heat dissipation part of the heat sink.

14. A loudspeaker apparatus, comprising:
a case;
a heat sink disposed on the case and including an external heat dissipation exposed on the case; and
a loudspeaker assembly disposed on the case,
wherein external airflow generated when the loudspeaker assembly vibrates to generate sound flows over the external heat dissipation part of the heat sink.
